(19) United States
(12) Patent Application Publication
(10) Pub. No.: US 2026/0140447 A1
(43) Pub. Date: May 21, 2026

(54) COMPOSITION, RESIST FILM, PATTERN FORMING METHOD, AND METHOD FOR PRODUCING ELECTRONIC DEVICE

(71) Applicant: FUJIFILM Corporation, Tokyo (JP)

(72) Inventors: Masafumi Kojima, Shizuoka (JP); Akiyoshi Goto, Shizuoka (JP)

(21) Appl. No.: 19/450,889

(22) Filed: Jan. 16, 2026

Related U.S. Application Data
(63) Continuation of application No. PCT/JP2024/024525, filed on Jul. 8, 2024.

(30) Foreign Application Priority Data
Jul. 26, 2023 (JP) 2023-121775

(51) Int. Cl. G03F 7/039; C08L 25/18; C08L 33/14; C08L 33/16; C08L 39/08; G03F 7/32; H10P 76/20

(52) U.S. Cl. CPC G03F 7/039; C08L 25/18; C08L 33/14; C08L 33/16; C08L 39/08; G03F 7/32; H10P 76/2041

(57) ABSTRACT

The present invention provides a composition from which a pattern having high resolution can be formed, and a resist film, a pattern forming method, and a method for producing an electronic device that are related to the composition. A composition according to the present invention includes a compound A having a plurality of groups represented by any one of formula (A1) to formula (A3), and a compound B having a plurality of specific functional groups selected from the group consisting of a nitrogen-containing aromatic heterocyclic group, —NH₂, an NH₂ group protected by a removable protecting group, —NHR^{N1} an NHR^{N1} group protected by a removable protecting group, —NR^{N2}₂, —C≡N, —OH, —OR^{O}, —SH, —SR^{S}, —PR^{P1}₂, and —P(OR^{P2})₂. The composition satisfies at least one of requirement 1 or requirement 2.

### CROSS-REFERENCE TO RELATED APPLICATIONS

This application is a Continuation of PCT International Application No. PCT/JP2024/024525 filed on Jul. 8, 2024, which claims priority under 35 U.S.C. § 119(a) to Japanese Patent Application No. 2023-121775 filed on Jul. 26, 2023. The above applications are hereby expressly incorporated by reference, in their entirety, into the present application.

### BACKGROUND OF THE INVENTION

### 1. Field of the Invention

The present invention relates to a composition, a resist film, a pattern forming method, and a method for producing an electronic device.

### 2. Description of the Related Art

Since the advent of a resist for KrF excimer laser (248 nm), pattern forming methods utilizing chemical amplification have been used in order to compensate for a decrease in sensitivity due to light absorption. For example, in a positive chemical amplification method, first, a photoacid generator included in exposed portions is decomposed upon photoirradiation to generate an acid. Subsequently, in a post exposure bake (PEB) process or the like, for example, an alkali-insoluble group of a resin included in an actinic ray-sensitive or radiation-sensitive resin composition is turned into an alkali-soluble group by the catalytic action of the generated acid to change the solubility in a developer. Development is then performed using, for example, a basic aqueous solution. As a result, the exposed portions are removed to obtain a desired pattern.

For miniaturization of semiconductor devices, the wavelengths of exposure light sources have been shortened and the numerical apertures (NAs) of projector lenses have been increased, and exposure devices using ArF excimer laser having a wavelength of 193 nm as a light source have now been developed. In recent years, pattern forming methods using extreme ultraviolet rays (EUV light) and an electron beam (EB) as light sources have also been studied. Under such circumstances, various configurations of resist compositions have been proposed.

For example, JP2021-004993A discloses “a resist composition including a base component whose solubility in a developer changes due to the action of acid, a compound represented by a specific structure and composed of an anion moiety and a cation moiety, and a fluorine additive including a fluorocarbon resin component having a specific constitutional unit”.

### SUMMARY OF THE INVENTION

The present inventors have studied the resist composition described in JP2021-004993A and found that a pattern formed using the resist composition has low resolution and needs to be further improved.

Specifically, the dimensions of a minimum pattern that was resolved without collapsing were investigated while varying the exposure dose during pattern exposure, and it was found that the dimensions of the pattern formed using the resist composition were not sufficiently small.

Thus, an object of the present invention is to provide a composition from which a pattern having high resolution can be formed.

Another object of the present invention is to provide a resist film, a pattern forming method, and a method for producing an electronic device that are related to the composition.

To achieve the above objects, the present inventors have conducted intensive studies and found that the objects can be achieved by the following configurations.

[1]A composition including:
a compound A having a plurality of groups that are each a group represented by any one of formula (A1) described below to formula (A3) described below; and
a compound B having a plurality of specific functional groups that are each a specific functional group selected from the group consisting of a nitrogen-containing aromatic heterocyclic group, —NH₂, an NH₂ group protected with a removable protecting group, —NHR^{N1}, an NHR^{N1} group protected with a removable protecting group, —NR^{N2}₂, —C≡N, —OH, —OR^{O}, —SH, —SR^{S}, —PR^{P1}₂, and —P(OR^{P2})₂
the composition satisfying at least one of requirement 1 or requirement 2:
Requirement 1: The compound A is a polymer having a repeating unit including the group represented by any one of formula (A1) to formula (A3),
Requirement 2: The compound B is a polymer having a repeating unit including the specific functional group,
wherein R^{N1}, R^{N2}, R^{O}, R_{S}, R^{P1}, and R^{P2} each independently represent a monovalent hydrocarbon group optionally having a substituent, Monovalent hydrocarbon groups represented by R^{N2} may be bonded to each other to form a ring, monovalent hydrocarbon groups represented by R^{P1} may be bonded to each other to form a ring, and monovalent hydrocarbon groups represented by R^{P2} may be bonded to each other to form a ring.

[2] The composition according to [1], wherein in formula (A1) to formula (A3), X represents a bromine atom or a chlorine atom.

[3] The composition according to [1] or [2], wherein in formula (A2), every R represents an electron-withdrawing group.

[4] The composition according to any one of [1] to [3], wherein in formula (A1), EWG represents a fluorine atom or a cyano group, and in formula (A2), at least one R represents a fluorine atom or a cyano group.

[5] The composition according to any one of [1] to [4], wherein the compound A is a compound having a plurality of groups represented by formula (A1).

[6] The composition according to any one of [1] to [5], wherein the specific functional group is a functional group selected from the group consisting of a nitrogen-containing aromatic heterocyclic group, NH₂—, an NH₂ group protected with a removable protecting group, NHR^{N1} an NHR^{N1} group protected with a removable protecting group, and NR^{N2}₂—.

[7] The composition according to any one of [1] to [6], satisfying requirement 1.

[8] The composition according to any one of [1] to [7], satisfying requirement 2.

[9]A resist film formed using the composition according to any one of [1] to [8].

[10]A pattern forming method including:
a step of forming a resist film on a substrate using the composition according to any one of [1] to [8];
a step of exposing the resist film; and
a step of developing the exposed resist film using a developer including an organic solvent.

[11]A method for producing an electronic device, the method including the pattern forming method according to [10].

The present invention can provide a composition from which a pattern having high resolution can be formed.

The present invention can also provide a resist film, a pattern forming method, and a method for producing an electronic device that are related to the composition.

### DESCRIPTION OF THE PREFERRED EMBODIMENTS

Hereinafter, the present invention will be described in detail.

It should be appreciated that although the following description of constituent features may be made in the context of a representative embodiment of the present invention, the present invention is not limited to the embodiment.

Hereinafter, the meanings of descriptions in the present specification will be described.

In the present specification, a numerical range expressed using “to” means a range including numerical values before and after “to” as lower and upper limit values.

In the present specification, a hydrogen atom may be a light hydrogen atom (normal hydrogen atom) or a heavy hydrogen atom (e.g., deuterium atom).

The term “organic group” as used herein refers to a group including at least one carbon atom.

A“substituent” in the present specification is preferably a monovalent substituent unless otherwise specified.

Examples of the substituent include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxaryl group; alkylsulfanyl groups such as a methylsulfanyl group and a tert-butylsulfanyl group; arylsulfanyl groups such as a phenylsulfanyl group and a p-tolylsulfanyl group; alkyl groups (linear, branched, and cyclic alkyl groups); aryl groups; heteroaryl groups; a hydroxy group; a carboxy group; a formyl group; a sulfo group; a cyano group; alkylaminocarbonyl groups; arylaminocarbonyl groups; a sulfonamide group; a silyl group; an amino group; monoalkylamino groups; dialkylamino groups; arylamino groups; alkylthio groups; and combinations thereof. In the specification, this group of substituents is also referred to as “substituents K”.

The bonding direction of a divalent group given in the present specification is not limited unless otherwise specified. For example, in a compound represented by a formula “X⁻Y—Z” where Y is —COO—, Y may be —CO—O— or —O—CO—. This compound may be represented as “X⁻CO—O—Z” or “X⁻O—CO—Z”.

Compounds described in the present specification may include their structural isomer, stereoisomer, and isotope unless otherwise specified. The structural isomer, stereoisomer, and isotope included may be of one type or two or more types.

As used herein, the term “(meth)acrylic” is a generic term including acrylic and methacrylic and means “at least one of acrylic or methacrylic”. Similarly, the term “(meth)acrylic acid” means “at least one of acrylic acid or methacrylic acid”.

The term “actinic ray” or “radiation” as used herein means, for example, an emission line spectrum of a mercury lamp, far ultraviolet rays typified by excimer lasers, extreme ultraviolet rays (EUV light), X-rays, or an electron beam (EB). The term “light” as used herein means an actinic ray or a radiation.

The term “exposure” as used herein includes, unless otherwise specified, not only exposure with, for example, an emission line spectrum of a mercury lamp, far ultraviolet rays typified by excimer lasers (e.g., ArF excimer laser), extreme ultraviolet rays, X-rays, or EUV light but also patterning with a corpuscular beam such as an electron beam or an ion beam.

In the present specification, a weight-average molecular weight (Mw), a number-average molecular weight (Mn), and a dispersity (also referred to as a molecular weight distribution) (Mw/Mn) of a resin are defined as polystyrene equivalent values determined by GPC measurement (solvent: tetrahydrofuran, flow rate (sample injection volume): 10 μL, column: TSK gel Multipore HXL-M manufactured by Tosoh Corporation, column temperature: 40° C., flow rate: 1.0 mL/min, detector: differential refractive index detector) using a gel permeation chromatography (GPC) apparatus (HLC-8120GPC manufactured by Tosoh Corporation), unless otherwise specified.

In the present specification, “ppm” means “parts per million (10⁻⁶)”, “ppb” means “parts per billion (10⁻⁹)”, and “ppt” means “parts per trillion (10⁻¹²)”.

In the present specification, the total solid contents are intended to mean components forming a resist film and do not include solvents. Any component forming a resist film is regarded as a solid content even in the form of liquid.

### Composition

Hereinafter, a composition (hereinafter also referred to as a “resist composition”) according to the present invention will be described in detail.

The resist composition according to the present invention is a composition including:
a compound A having a plurality of groups that are each a group represented by any one of formula (A1) described below to formula (A3) described below; and
a compound B having a plurality of specific functional groups that are each a specific functional group selected from the group consisting of a nitrogen-containing aromatic heterocyclic group, —NH₂, an NH₂ group protected with a removable protecting group, —NHR^{N1}, an NHR^{N1} group protected with a removable protecting group, —NR^{N2}₂, —C≡N, —OH, —OR^{O}, —SH, —SR^{S}, —PR^{P1}₂, and —P(OR^{P2})₂
the composition satisfying at least one of requirement 1 described below or requirement 2 described below.

Although the mechanism by which the resist composition according to the present invention having the above configuration can achieve the objects of the present invention is not necessarily clear, the present inventors presume as follows.

It should be noted that the following presumption does not limit the mechanism by which the effect is obtained. In other words, cases where the effect is obtained by mechanisms other than the following are also within the scope of the present invention.

The resist composition according to the present invention, when in the form of an unexposed resist film, is insoluble in a developer because the compound A and the compound B included in the resist composition form a strong halogen bond so that the resist film has a crosslinked structure throughout. When exposure treatment is performed here, carbon-halogen bonds are cleaved to eliminate the crosslinked structure, and as a result, the resist film in exposed portions becomes soluble in the developer, so that a resist pattern can be formed.

Here, the resist composition disclosed in JP2021-004993A is a so-called chemically amplified resist composition, and has a problem in that its resolution is low because reaction proceeds even in unexposed portions of a resist film that are not irradiated with light.

By contrast, for the resist composition according to the present invention, only carbon-halogen bonds that have been exposed to light are cleaved as described above, and thus the reaction in unexposed portions hardly proceeds, presumably resulting in a resist pattern with higher resolution.

Hereinafter, requirement 1 and requirement 2 will be described in detail.

### Requirement 1 and Requirement 2

The resist composition according to the present invention satisfies at least one of requirement 1 or requirement 2.

Requirement 1: The compound A is a polymer having a repeating unit including a group represented by any one of formula (A1) to formula (A3).

Requirement 2: The compound B is a polymer having a repeating unit including a specific functional group.

When the resist composition satisfies at least one of requirement 1 or requirement 2, a resist film obtained by using the resist composition is homogeneous.

The resist composition may satisfy both requirement 1 and requirement 2.

When the resist composition satisfies requirement 1, the weight-average molecular weight of the compound A is preferably 1,000 to 10,000, more preferably 1,000 to 5,000.

When the resist composition satisfies requirement 1, the number of groups represented by any one of formula (A1) to formula (A3) in the repeating unit is preferably 1 to 4, more preferably 1 or 2, still more preferably 1, per repeating unit.

When the resist composition satisfies requirement 2, the weight-average molecular weight of the compound B is preferably 1,000 to 10,000, more preferably 1,000 to 5,000.

When the resist composition satisfies requirement 2, the number of specific functional groups is preferably 1 to 4, more preferably 1 or 2, still more preferably 1, per repeating unit.

Hereinafter, the components included in the resist composition according to the present invention will be described in detail.

### Compound A

The resist composition according to the present invention includes the compound A.

The compound A is a compound having a plurality of groups represented by any one of formula (A1) to formula (A3), and a plurality of halogen atoms in the compound A behave as electron acceptors to form multipoint halogen bonds with the compound B described later, whereby a resist film can be formed.

When the resist composition does not satisfy requirement 1, the molecular weight of the compound A is preferably 300 to 2,000, more preferably 800 to 2,000.

When the resist composition does not satisfy requirement 1, the compound A preferably has three or more groups, more preferably has four or more groups, represented by any one of formula (A1) to formula (A3). The upper limit is not particularly limited, and may be, for example, 10 or less.

As described above, the compound A is a compound having a plurality of groups represented by any one of formula (A1) to formula (A3).

The compound A is preferably a compound having a plurality of groups represented by formula (A1).

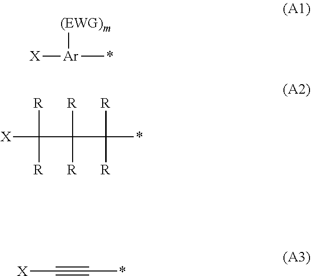

In formula (A1),
X represents an iodine atom, a bromine atom, or a chlorine atom.
EWG represents an electron-withdrawing group.
m represents an integer of 4 or more.
Ar represents an aromatic hydrocarbon ring optionally having a substituent.

In formula (A2),
X represents an iodine atom, a bromine atom, or a chlorine atom.

Each R independently represents a hydrogen atom or a substituent. At least one R represents an electron-withdrawing group.

In formula (A3),
X represents an iodine atom, a bromine atom, or a chlorine atom.
* represents a bonding position.

In formula (A1) to formula (A3), X represents an iodine atom, a bromine atom, or a chlorine atom.

X preferably represents a bromine atom or a chlorine atom.

In formula (A1), when X is a bromine atom and the electron-withdrawing group represented by EWG is a halogen atom, the electron-withdrawing group represented by EWG is preferably a chlorine atom or a fluorine atom.

In formula (A1), when X is a chlorine atom and the electron-withdrawing group represented by EWG is a halogen atom, the electron-withdrawing group represented by EWG is preferably a fluorine atom.

In formula (A2), when X is a bromine atom and the electron-withdrawing group represented by at least one R is a halogen atom, the electron-withdrawing group represented by R is preferably a chlorine atom or a fluorine atom.

In formula (A2), when X is a chlorine atom and the electron-withdrawing group represented by at least one R is a halogen atom, the electron-withdrawing group represented by R is preferably a fluorine atom.

In formula (A1) and formula (A2), the electron-withdrawing group represented by EWG and the electron-withdrawing group represented by R are, for example, those having a positive Hammett substituent constant (ap value). The Hammett substituent constant is a numerical value representing the effect of a substituent on the acid dissociation equilibrium constant of a substituted benzoic acid and is a parameter indicating the degree of the electron-withdrawing properties and electron-donating properties of the substituent. The Hammett substituent constant in this specification means a substituent constant σ in the case where the substituent is located at the para position of benzoic acid.

Hammett substituent constants (σp values) can be cited from “Hansch et al., Chemical Reviews, 1991, Vol. 91, No. 2, 165-195”.

For a group whose σp value is not disclosed in this literature, the σp value can be calculated using the software “ACD/ChemSketch (ACD/Labs 8.00 Release Product Version: 8.08)” on the basis of the difference between the pKa of benzoic acid and the pKa of a benzoic acid derivative having the substituent at the para position.

Examples of the electron-withdrawing groups include —F (σp: +0.06), —Cl (σp: +0.23), —Br (σp: +0.23), —CO₂R^{EWG} (σp: +0.45, in the case where R^{EWG} is an ethyl group), —CONH₂ (σp: +0.36), —COR^{EWG} (σp: +0.50, in the case where R^{EWG} is a methyl group), —CF₃ (σp: +0.54), —SO₂R^{EWG} (σp: +0.72, in the case where R^{EWG} is a methyl group), and —NO₂ (σp: +0.78).

Each R^{EWG} independently represents a hydrogen atom, an aliphatic hydrocarbon group optionally having a substituent, or an aromatic ring group optionally having a substituent.

Examples of the substituent include the substituents K.

In particular, the electron-withdrawing group is preferably a fluorine atom, an aryl group having a fluorine atom, a fluoroalkyl group, or a cyano group.

In formula (A1), m represents an integer of 4 or more.

m is preferably an integer of 4 to 8, more preferably an integer of 4 to 6, still more preferably 4.

The aromatic hydrocarbon ring optionally having a substituent, as represented by Ar, may be monocyclic or polycyclic. Ar corresponds to an (m+n+1)-valent group.

The number of ring atoms of the aromatic hydrocarbon ring is preferably 6 to 20, more preferably 6 to 10, still more preferably 6.

Examples of the substituent that the aromatic hydrocarbon ring optionally has include the substituents K.

In particular, the aromatic hydrocarbon ring optionally having a substituent is preferably a benzene ring optionally having a substituent, and is more preferably a benzene ring having no substituents other than halogen atoms and electron-withdrawing groups.

In formula (A2),
each R independently represents a hydrogen atom or a substituent. At least one R represents an electron-withdrawing group.

R preferably represents a hydrogen atom or an electron-withdrawing group, and more preferably, every R in formula (A2) represents an electron-withdrawing group.

Examples of the electron-withdrawing group include the groups exemplified as electron-withdrawing groups, as described above.

In particular, the electron-withdrawing group represented by R is preferably a fluorine atom or a cyano group.

Specifically, the compound A may be a compound represented by formula (X1) or formula (X2).

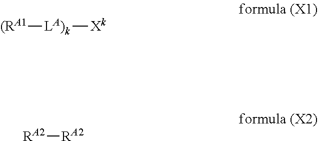

In formula (X1),
each R^{A1} independently represents a group represented by any one of formula (A1) to formula (A3) described above.
Each L^{A} independently represents a single bond or a divalent linking group.
X^{k} represents a k-valent linking group. k represents an integer of 2 or more.

In formula (X2),
each R^{A2} independently represents a group represented by any one of formula (A1) to formula (A3) described above.

In formula (X1) and formula (X2), the definition and preferred form of the group represented by any one of formula (A1) to formula (A3) are as described above.

In formula (X1), each L^{A} independently represents a single bond or a divalent linking group.

Examples of the divalent linking group represented by L^{A} include —O—, —CO—, —S—, —SO—, —SO₂, an alkylene group, an alkenylene group, an arylene group, a heteroarylene group, and a linking group formed by linkage of two or more thereof.

The alkylene group and the alkenylene group may be linear, branched, or cyclic, and the number of carbon atoms thereof is preferably 1 to 10, more preferably 1 to 5, still more preferably 1 or 2.

The number of carbon atoms of the arylene group is preferably 6 to 10, more preferably 6.

The number of carbon atoms of the heteroarylene group is preferably 4 to 10, more preferably 4 or 5.

The arylene group and the heteroarylene group may be monocyclic or polycyclic.

Examples of the group formed by linkage of two or more divalent linking groups include —COO—, —OCO—, —O-alkylene group-, —COO-alkylene group-, and —OCO-alkylene group-.

In the k-valent linking group represented by X^{k}, k represents an integer of 2 or more, preferably an integer of 2 to 6, more preferably an integer of 2 to 4.

Examples of the divalent linking group represented by X^{k} include —O—, —CO—, —S—, —SO—, —SO₂, an alkylene group, an alkenylene group, an arylene group, a heteroarylene group, and a linking group formed by linkage of two or more thereof (e.g., a biphenylene group).

The definitions and preferred forms of the above groups are as described in detail for the divalent linking group represented by L^{A}.

The divalent linking group represented by X^{k} is preferably an alkenylene group having 1 to 3 carbon atoms, a phenylene group, or a biphenylene group.

The trivalent linking group represented by X^{k} may be a trivalent aromatic ring group or a nitrogen atom (—N<). The trivalent aromatic ring group refers to a group formed by removing three hydrogen atoms on ring atoms from an aromatic hydrocarbon ring optionally having a substituent or an aromatic heterocyclic ring optionally having a substituent. It may be, for example, a group formed by removing three hydrogen atoms on ring atoms of a benzene ring or a biphenyl ring.

The aromatic hydrocarbon ring and the aromatic heterocyclic ring may be monocyclic or polycyclic.

Examples of the substituent include the substituents K, and in particular, the substituent is preferably an alkyl group or an electron-withdrawing group, more preferably a fluorine atom. The number of carbon atoms of the alkyl group is preferably 1 to 3.

The tetravalent linking group represented by X^{k} may be, for example, a carbon atom (>C<), a silicon atom (>Si<), or a tetravalent aromatic ring group. The tetravalent aromatic ring group refers to a group formed by removing four hydrogen atoms on ring atoms from an aromatic hydrocarbon ring optionally having a substituent or an aromatic heterocyclic ring optionally having a substituent. It may be, for example, a group formed by removing four hydrogen atoms on ring atoms of a benzene ring or a biphenyl ring.

The aromatic hydrocarbon ring and the aromatic heterocyclic ring may be monocyclic or polycyclic.

Examples of the substituent include the substituents K, and in particular, the substituent is preferably an alkyl group or an electron-withdrawing group, more preferably a fluorine atom. The number of carbon atoms of the alkyl group is preferably 1 to 3.

### Repeating Unit A1 (Repeating Unit Having Group Represented by Any One of Formula (A1) to Formula (A3))

When the resist composition satisfies requirement 1, the compound A preferably has a repeating unit represented by formula (U1) as the repeating unit having a group represented by any one of formula (A1) to formula (A3) (hereinafter also referred to as “repeating unit A1”).

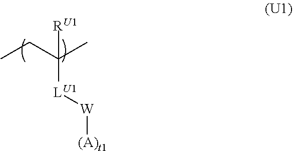

In formula (U1), R^{U1} represents a hydrogen atom or an alkyl group.

The alkyl group may be linear or branched. The number of carbon atoms of the alkyl group is preferably 1 to 5, more preferably 1 to 2.

L^{U1} represents a single bond or a divalent linking group.

Examples of the divalent linking group include —O—, —CO—, —S—, —SO—, —SO₂, an alkylene group, an alkenylene group, an arylene group, a heteroarylene group, and a linking group formed by linkage of two or more thereof.

The alkylene group, the alkenylene group, the arylene group, and the heteroarylene group may each have a substituent. Examples of the substituent include the substituents K.

The alkylene group and the alkenylene group may be linear, branched, or cyclic, and the number of carbon atoms thereof is preferably 1 to 10, more preferably 1 to 5, still more preferably 1 or 2.

The number of carbon atoms of the arylene group is preferably 6 to 10, more preferably 6.

The number of carbon atoms of the heteroarylene group is preferably 4 to 10, more preferably 4 or 5.

The arylene group and the heteroarylene group may be monocyclic or polycyclic.

Examples of the group formed by linkage of two or more divalent linking groups include —COO—, —OCO—, —O-alkylene group-, —COO-alkylene group-, and —OCO-alkylene group-.

In particular, L^{U1} is preferably —COO— or —COO-alkylene group-.

W represents a single bond or a ((t1)+1)-valent linking group. t1 represents an integer of 1 or more. The upper limit is not particularly limited, but is preferably 5 or less, more preferably 2 or less, still more preferably 1.

The ((t1)+1)-valent linking group may be a group formed by removing ((t1)-1) hydrogen atoms from the divalent linking group represented by L^{U1}.

W is preferably a single bond.

Each A independently represents a group represented by any one of formula (A1) to formula (A3) described above. The definition and preferred form of the group represented by any one of formula (A1) to formula (A3) are as described above.

When a plurality of groups represented by A are present, the plurality of groups represented by A may be the same or different.

The repeating unit A1 may be used alone or in combination of two or more.

When the compound A has the repeating unit A1, the content of the repeating unit A1 is preferably 50 to 100 mol %, more preferably 70 to 100 mol %, relative to all the repeating units.

### Other Repeating Units

The compound A may have other repeating units other than the repeating unit A1.

Examples of the other repeating units include a repeating unit having an alkyl group optionally having a substituent, a repeating unit having a lactone group, a sultone group, or a carbonate group, and a repeating unit derived from an aromatic vinyl compound.

### Repeating Unit A2 (Repeating Unit Having Alkyl Group Optionally Having Substituent)

The compound A may have a repeating unit having an alkyl group optionally having a substituent (hereinafter also referred to as “repeating unit A2”).

The alkyl group may be linear, branched, or cyclic. In the case of a cyclic alkyl group, it may have a monocyclic structure or a polycyclic structure.

The number of carbon atoms of the alkyl group is not particularly limited, and is, for example, 1 to 20.

Examples of the substituent that the alkyl group optionally has include the substituents K described above, and a more specific example is a hydroxy group.

The repeating unit A2 is preferably a repeating unit represented by formula (A).

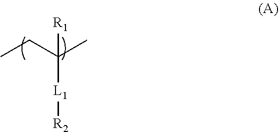

R₁ represents a hydrogen atom, a fluorine atom, an iodine atom, an alkyl group, or an aryl group, L₁ represents a divalent linking group, and R₂ represents an alkyl group optionally having a substituent.

R₁ represents a hydrogen atom, a fluorine atom, an iodine atom, an alkyl group, or an aryl group. The alkyl group and the aryl group may have a fluorine atom or an iodine atom as a substituent.

The alkyl group may be linear or branched. The number of carbon atoms of the alkyl group is not particularly limited, but is preferably 1 to 10, more preferably 1 to 3.

The total number of fluorine atoms and iodine atoms that the alkyl group optionally has is not particularly limited, but is preferably 1 or more, more preferably 1 to 5, still more preferably 1 to 3.

The alkyl group may have a heteroatom such as an oxygen atom.

L₁ represents a divalent linking group.

Examples of the divalent linking group include —CO—, —O—, —S—, —SO—, —SO₂, a divalent hydrocarbon group (e.g., an alkylene group, a cycloalkylene group, an alkenylene group, or an arylene group), and a linking group formed by linkage of two or more thereof.

The divalent hydrocarbon group may have a fluorine atom or an iodine atom as a substituent.

In particular, L₁ is preferably —CO—, -Rt-, —COO-Rt-, —COO-Rt-CO—, or -Rt-CO—, more preferably —CO— or —COO-Rt-CO—. Rt is a divalent hydrocarbon group, and is preferably an alkylene group or an arylene group, more preferably an alkylene group.

The arylene group is preferably a phenylene group.

The alkylene group may be linear or branched. The number of carbon atoms of the alkylene group is not particularly limited, but is preferably 1 to 10, more preferably 1 to 3.

The total number of fluorine atoms and iodine atoms included in the alkylene group having a fluorine atom or an iodine atom is not particularly limited, but is preferably 2 or more, more preferably 2 to 10, still more preferably 3 to 6.

R₂ represents an alkyl group optionally having a substituent.

The alkyl group may be linear, branched, or cyclic. In the case of a cyclic alkyl group, it may have a monocyclic structure or a polycyclic structure.

The number of carbon atoms of the alkyl group is not particularly limited, and is, for example, 1 to 20.

Examples of the cyclic alkyl group include monocyclic alkyl groups (cycloalkyl groups) such as a cyclopentyl group and a cyclohexyl group, and polycyclic cycloalkyl groups such as a norbornyl group, a tricyclodecanyl group, a tetracyclodecanyl group, a tetracyclododecanyl group, and an adamantyl group.

Examples of the substituent that the alkyl group optionally has include the substituents K described above, and a more specific example is a hydroxy group.

The repeating unit A2 may be used alone or in combination of two or more.

When the compound A has the repeating unit A2, the content of the repeating unit A2 is preferably 1 to 50 mol %, more preferably 10 to 30 mol %, relative to all the repeating units. Repeating Unit A3 (Repeating Unit Having Lactone Group, Sultone Group, or Carbonate Group)

The compound A may have a repeating unit having at least one selected from the group consisting of a lactone group, a sultone group, and a carbonate group (hereinafter also referred to as “repeating unit A3”).

It is also preferred that the repeating unit A3 not have an acid group such as a hydroxy group or a hexafluoropropanol group.

The repeating unit A3 may have an iodine atom, a bromine atom, or a chlorine atom, but preferably does not have these atoms.

The lactone group or the sultone group has a lactone structure or a sultone structure. The lactone structure or the sultone structure is preferably a 5- to 7-membered lactone structure or a 5- to 7-membered sultone structure.

In particular, a 5- to 7-membered lactone structure to which another ring structure is fused so as to form a bicyclo structure or a spiro structure, or a 5- to 7-membered sultone structure to which another ring structure is fused so as to form a bicyclo structure or a spiro structure is more preferred.

The compound A preferably has a repeating unit having a lactone group or a sultone group formed by abstracting one or more hydrogen atoms from a ring atom of a lactone structure represented by any one of formulas (LC1-1) to (LC1-21) below or a sultone structure represented by any one of formulas (SL1-1) to (SL1-3) below.

The lactone group or the sultone group may be directly bonded to the main chain.

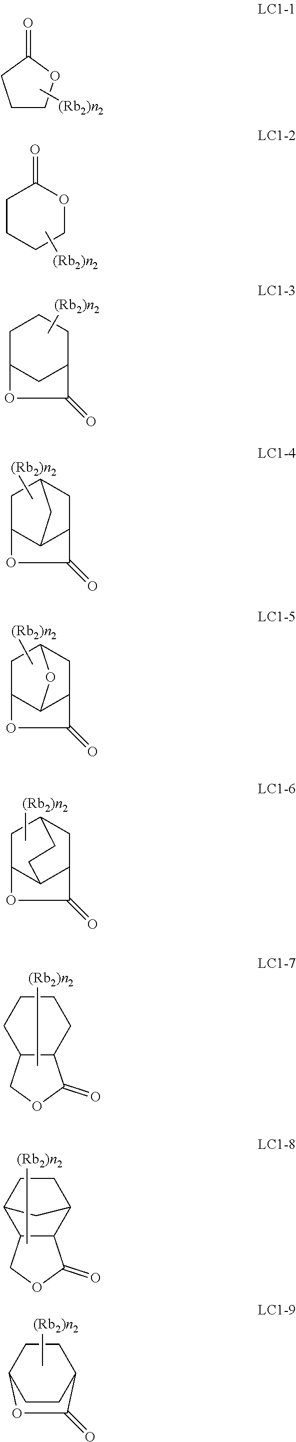

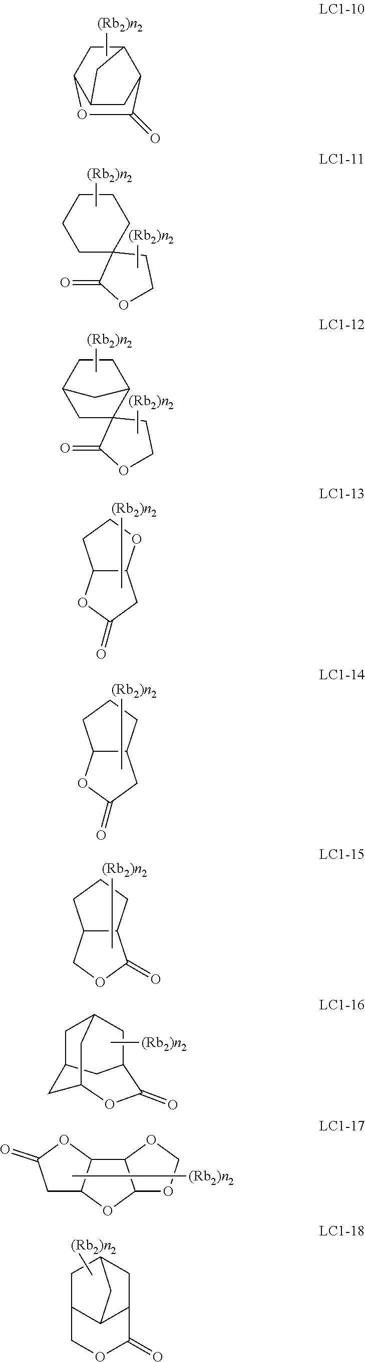

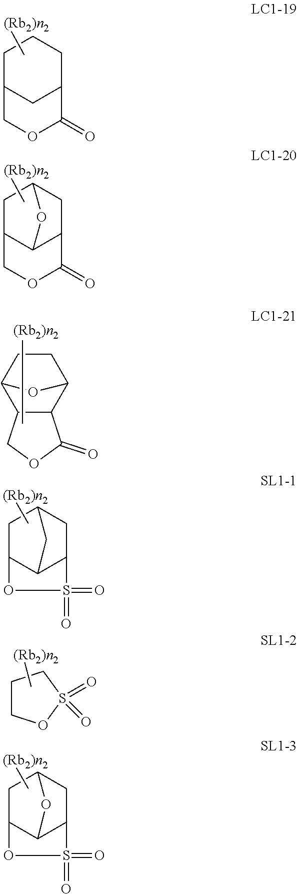

The lactone structure or the sultone structure may have a substituent (Rb₂).

The substituent (Rb₂) is preferably an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxy group, a halogen atom, a cyano group, or an acid-decomposable group.

n2 represents an integer of 0 to 4. When n2 is 2 or more, the plurality of Rb₂'s may be different from each other, and the plurality of Rb₂'s may be bonded together to form a ring.

One example of the repeating unit A3 is a repeating unit represented by formula (AI) below.

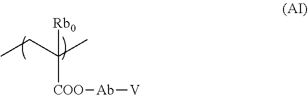

In formula (AI), Rb₀ represents a hydrogen atom, a halogen atom, or an alkyl group having 1 to 4 carbon atoms. Preferred substituents that the alkyl group represented by Rb₀ optionally has include a hydroxy group and a halogen atom. Examples of the halogen atom include a fluorine atom, a chlorine atom, a bromine atom, and an iodine atom.

Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxy group, or a divalent linking group that is a combination thereof. Ab is preferably a single bond or a linking group represented by -Ab₁CO₂—. Ab₁ is a linear or branched alkylene group or a monocyclic or polycyclic cycloalkylene group, and is preferably a methylene group, an ethylene group, a cyclohexylene group, an adamantylene group, or a norbornylene group.

V represents a group formed by abstracting one hydrogen atom from a ring atom of a lactone structure represented by any one of formulas (LC1-1) to (LC1-21) or a group formed by abstracting one hydrogen atom from a ring atom of a sultone structure represented by any one of formulas (SL1-1) to (SL1-3).

The carbonate group is preferably a cyclic carbonic acid ester group.

Examples of the repeating unit A3 also include repeating units described in paragraphs [0104] to [0110] of WO2020/158467A.

The repeating unit A3 may be used alone or in combination of two or more.

When the compound A has the repeating unit A3, the content of the repeating unit A3 is preferably 1 to 50 mol %, more preferably 5 to 25 mol %, relative to all the repeating units. Repeating Unit A4 (Repeating Unit Derived from Aromatic Vinyl Compound)

The compound A may have a repeating unit derived from an aromatic vinyl compound (hereinafter also referred to as “repeating unit A4”).

The aromatic vinyl compound is not particularly limited as long as it is an olefin compound having an aromatic ring structure, and may be a chain olefin compound or a cyclic olefin compound.

The monovalent aromatic group is not particularly limited, and may be an aryl group optionally having a substituent or a heteroaryl group optionally having a substituent, but is preferably an aryl group optionally having a substituent. Specific forms of the monovalent aromatic group will be described later.

One example of the repeating unit A4 is a repeating unit represented by formula (AX) below.

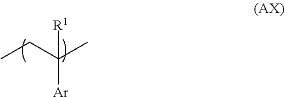

In formula (AX), R¹ represents a hydrogen atom or an alkyl group optionally having a substituent.

The number of substituents that the alkyl group optionally has is not particularly limited, and is preferably 1 to 4, more preferably 1 or 2. R¹ is preferably a hydrogen atom.

Examples of the substituent that the alkyl group optionally has include the groups exemplified as the substituents K.

The number of carbon atoms of the alkyl group (alkyl group moiety not including a substituent) is preferably 1 to 20, more preferably 1 to 6, still more preferably 1 or 2, particularly preferably 1.

The alkyl group may be linear, branched, or cyclic, and examples include linear or branched alkyl groups such as a methyl group, an ethyl group, a n-propyl group, an i-propyl group, a n-butyl group, a t-butyl group, and a n-hexyl group; monocyclic cycloalkyl groups such as a cyclopentyl group and a cyclohexyl group; and polycyclic cycloalkyl groups such as a norbornyl group, a tetracyclodecanyl group, a tetracyclododecanyl group, and an adamantyl group.

In particular, the alkyl group is preferably a linear alkyl group, more preferably a linear alkyl group having 1 to 5 carbon atoms, still more preferably a methyl group or an ethyl group, particularly preferably a methyl group.

In formula (AX), Ar represents a monovalent aromatic group optionally having a substituent.

The number of substituents that the monovalent aromatic group optionally has is not particularly limited, and is preferably 1 to 4, more preferably 1 or 2.

Examples of the substituent that the monovalent aromatic group optionally has include the groups exemplified as the substituents K. In particular, the substituent that the monovalent aromatic group optionally has is preferably an alkyl group optionally having a halogen atom, more preferably an alkyl group optionally having a fluorine atom. When the alkyl group has a fluorine atom, it may be a perfluoroalkyl group.

The alkyl group may be linear, branched, or cyclic.

In particular, the alkyl group is preferably a linear or branched alkyl group, more preferably a linear or branched alkyl group having 1 to 5 carbon atoms, still more preferably a methyl group, an ethyl group, a n-propyl group, an i-propyl group, a n-butyl group, or a t-butyl group.

The monovalent aromatic group is not particularly limited, and may be monocyclic or polycyclic, and may be an aryl group or a heteroaryl group.

The number of ring atoms of the monovalent aromatic group is preferably 6 to 15, more preferably 6 to 10.

The monovalent aromatic group is preferably an aryl group, more preferably a phenyl group, a naphthyl group, or an anthracenyl group, still more preferably a phenyl group.

In particular, the monovalent aromatic group optionally having a substituent, as represented by Ar, is preferably an aryl group optionally having a substituent, more preferably a phenyl group, naphthyl group, or anthracenyl group optionally having a substituent, still more preferably a phenyl group optionally having a t-butyl group or a trifluoromethyl group, particularly preferably a phenyl group. When the phenyl group has a substituent, the substituent is preferably located at the para position on the phenyl group.

The aromatic vinyl compound may be α-methylstyrene or a derivative thereof. That is, in formula (AX), R¹ may be a methyl group, and Ar may be a phenyl group optionally having a substituent.

### Repeating Unit Represented by Formula (V-1) or Formula (V-2)

The repeating unit A4 may be a repeating unit represented by formula (V-1) below or formula (V-2) below.

The repeating unit represented by formula (V-1) below and the repeating unit represented by formula (V-2) below are preferably repeating units different from the above-described repeating units.

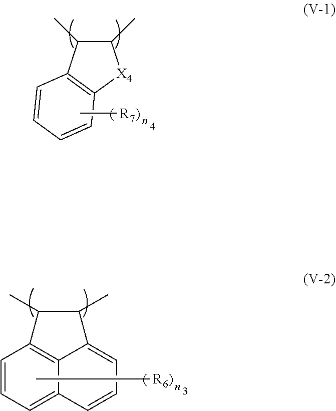

In formulas (V-1) and (V-2), R₆ and R₇ each independently represent a hydrogen atom, a hydroxy group, an alkyl group, an alkoxy group, an acyloxy group, a cyano group, a nitro group, an amino group, a halogen atom, an ester group (—OCOR or —COOR: R is an alkyl group or fluorinated alkyl group having 1 to 6 carbon atoms), or a carboxyl group.

The alkyl group is preferably a linear, branched, or cyclic alkyl group having 1 to 10 carbon atoms.

In formula (V-1), n₄ represents an integer of 0 to 4. X₄ represents a methylene group, an oxygen atom, or a sulfur atom.

In formula (V-2), n₃ represents an integer of 0 to 6.

Examples of the repeating unit represented by formula (V-1) or formula (V-2) include repeating units shown in paragraph [0100] of WO2018/193954A.

The repeating unit A4 may be used alone or in combination of two or more.

When the compound A has the repeating unit A4, the content of the repeating unit A4 is preferably 1 to 50 mol %, more preferably 10 to 45 mol %, relative to all the repeating units.

The compound A may be used alone or in combination of two or more.

The content of the compound A is preferably 5 to 80 mass %, more preferably 15 to 70 mass %, still more preferably 15 to 60 mass %, relative to the total solid contents of the resist composition.

### Compound B

The resist composition according to the present invention includes the compound B.

The compound B, because of having the plurality of specific functional groups, behaves as an electron donor to form multipoint halogen bonds with the compound A, whereby a resist film can be formed.

When the resist composition does not satisfy requirement 2, the molecular weight of the compound B is preferably 200 to 1,000, more preferably 400 to 1,000.

When the resist composition does not satisfy requirement 2, the compound B preferably has three or more specific functional groups, more preferably four or more specific functional groups. The upper limit is not particularly limited, and may be, for example, 10 or less.

The compound B is a compound having a plurality of specific functional groups selected from the group consisting of a nitrogen-containing aromatic heterocyclic group, —NH₂, an NH₂ group protected with a removable protecting group, NHR^{N1}—, an NH^{N1} group protected with a removable protecting group, —NR^{N2}₂, —C≡N, —OH, —OR^{O}, —SH, —SR^{S}, —PR^{P1}₂, and —P(OR^{P2})₂ and not having an iodine atom bonded to a carbon atom.

R^{N1}, R^{N2}, R^{O}, R^{S}, R^{P1}, and R^{P2} each independently represent a monovalent hydrocarbon group optionally having a substituent. Monovalent hydrocarbon groups represented by R^{N2} may be bonded to each other to form a ring, monovalent hydrocarbon groups represented by R^{P1} may be bonded to each other to form a ring, and monovalent hydrocarbon groups represented by R^{P2} may be bonded to each other to form a ring.

The nitrogen-containing aromatic heterocyclic group refers to a group formed by removing one hydrogen atom on a ring atom from a nitrogen-containing aromatic heterocyclic ring. The ring structure may be monocyclic or polycyclic.

Examples of the nitrogen-containing aromatic heterocyclic ring in the nitrogen-containing aromatic heterocyclic group include imidazole, pyridine, pyrrole, pyrazole, triazole, triazine, benzimidazole, and benzotriazole.

In NH^{N1}—, the NHR^{N1} group protected with a removable protecting group, and NR^{N2}₂—, R^{N1} and R^{N2} each independently represent a monovalent hydrocarbon group optionally having a substituent. Monovalent hydrocarbon groups represented by R^{N2} may be bonded to each other to form a ring.

Examples of the monovalent hydrocarbon group include an aliphatic hydrocarbon group and an aromatic hydrocarbon group.

The aliphatic hydrocarbon group may be linear, branched, or cyclic. The number of carbon atoms of the aliphatic hydrocarbon group is preferably 1 to 6, more preferably 1 to 3.

The aromatic hydrocarbon group may be monocyclic or polycyclic. The number of carbon atoms of the aromatic hydrocarbon group is preferably 6 to 10.

In particular, the monovalent hydrocarbon group is preferably an alkyl group having 1 to 3 carbon atoms.

In the NH₂ group protected by a removable protecting group and the NHR^{N1} group protected by a removable protecting group, the term “removable protecting group” refers to a functional group that is eliminated under the action of, for example, heat, an acid, a base, a reducing agent, or other reagents.

The protecting group is preferably a protecting group that undergoes deprotection upon heating, and may be, for example, a carbamate protecting group. More specifically, the carbamate protecting group may be a tert-butoxycarbonyl group, a tert-pentoxycarbonyl group, a benzyloxycarbonyl group, a 9-fluorenylmethyloxycarbonyl group, a 2,2,2-trichloroethoxycarboxyl group, or an allyloxycarbonyl group, and is preferably a tert-butoxycarbonyl group or a tert-pentoxycarbonyl group.

In —OR^{O}, —SR^{S}, —PR^{P1}₂, and —P(OR^{P2})₂, R^{O}, R^{S}, R^{P1}, and R^{P2} each independently represent a monovalent hydrocarbon group optionally having a substituent.

Examples of the monovalent hydrocarbon group include an aliphatic hydrocarbon group and an aromatic hydrocarbon group.

The aliphatic hydrocarbon group may be linear, branched, or cyclic. The number of carbon atoms of the aliphatic hydrocarbon group is preferably 1 to 6, more preferably 1 to 3.

The aromatic hydrocarbon group may be monocyclic or polycyclic. The number of carbon atoms of the aromatic hydrocarbon group is preferably 6 to 10.

In particular, the monovalent hydrocarbon group is preferably a linear or branched alkyl group having 1 to 6 carbon atoms, or a phenyl group.

In particular, the specific functional group is preferably a functional group selected from the group consisting of a nitrogen-containing aromatic heterocyclic group, NH₂—, an NH₂ group protected with a removable protecting group, NHR^{N1}—, an NH^{N1} group protected with a removable protecting group, and NR^{N2}₂—.

Specifically, the compound B may be a compound represented by formula (Y1) or formula (Y2).

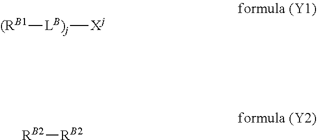

In formula (Y1),
each R^{B1} independently represents the specific functional group.
Each L^{B} independently represents a single bond or a divalent linking group.
X^{j} represents a j-valent linking group. j represents an integer of 2 or more.

In formula (Y2),
each R^{B2} independently represents the specific functional group.

In formulas (Y1) and (Y2), the definition and preferred form of the specific functional group are as described above.

In formula (Y1), each L^{B} independently represents a single bond or a divalent linking group.

Examples of the divalent linking group represented by L^{B} include —O—, —CO—, —S—, —SO—, —SO₂, an alkylene group, an alkenylene group, an arylene group, a heteroarylene group, and a linking group formed by linkage of two or more thereof.

The alkylene group and the alkenylene group may be linear, branched, or cyclic, and the number of carbon atoms thereof is preferably 1 to 10, more preferably 1 to 5, still more preferably 1 or 2.

The number of carbon atoms of the arylene group is preferably 6 to 10, more preferably 6.

The number of carbon atoms of the heteroarylene group is preferably 4 to 10, more preferably 4 or 5.

The arylene group and the heteroarylene group may be monocyclic or polycyclic.

Examples of the group formed by linkage of two or more divalent linking groups include —COO—, —OCO—, —O-alkylene group-, —COO-alkylene group-, —OCO-alkylene group-, and -alkylene group-OCO-alkylene group-.

In the j-valent linking group represented by X^{j}, j represents an integer of 2 or more, preferably 2 to 6, more preferably 2 to 4.

Examples of the divalent linking group represented by X^{j} include —O—, —CO—, —S—, —SO—, —SO₂, an alkylene group, an alkenylene group, an arylene group, a heteroarylene group, and a linking group formed by linkage of two or more thereof.

The definitions and preferred forms of the above groups are as described in detail for the divalent linking group represented by L^{B}.

The divalent linking group represented by X^{j} is preferably an alkenylene group having 1 to 3 carbon atoms or a phenylene group.

The trivalent linking group represented by X^{j} may be a trivalent aromatic ring group or a nitrogen atom (—N<). The trivalent aromatic ring group refers to a group formed by removing three hydrogen atoms on ring atoms from an aromatic hydrocarbon ring optionally having a substituent or an aromatic heterocyclic ring optionally having a substituent. It may be, for example, a group formed by removing three hydrogen atoms on ring atoms of a benzene ring or a biphenyl ring.

The aromatic hydrocarbon ring and the aromatic heterocyclic ring may be monocyclic or polycyclic.

Examples of the substituent include the substituents K.

The tetravalent linking group represented by X^{j} may be, for example, a carbon atom (>C<), a silicon atom (>Si<), or a tetravalent aromatic ring group. The tetravalent aromatic ring group refers to a group formed by removing four hydrogen atoms on ring atoms from an aromatic hydrocarbon ring optionally having a substituent or an aromatic heterocyclic ring optionally having a substituent. It may be, for example, a group formed by removing four hydrogen atoms on ring atoms of a benzene ring or a biphenyl ring.

The aromatic hydrocarbon ring and the aromatic heterocyclic ring may be monocyclic or polycyclic.

Examples of the substituent include the substituents K.

### Repeating Unit B1 (Repeating Unit Including Specific Functional Group)

When the resist composition satisfies requirement 1, the compound B preferably has a repeating unit represented by formula (U2) as the repeating unit including a specific functional group (hereinafter also referred to as “repeating unit B1”).

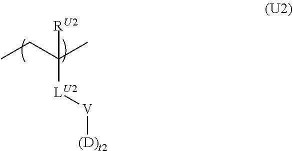

In formula (U2), R^{U2} represents a hydrogen atom or an alkyl group.

The alkyl group may be linear or branched. The number of carbon atoms of the alkyl group is preferably 1 to 5, more preferably 1 to 2.

In formula (U2), L^{U2} represents a single bond or a divalent linking group.

Examples of the divalent linking group include —O—, —CO—, —S—, —SO—, —SO₂, an alkylene group, an alkenylene group, an arylene group, a heteroarylene group, and a linking group formed by linkage of two or more thereof.

The alkylene group, the alkenylene group, the arylene group, and the heteroarylene group may each have a substituent. Examples of the substituent include the substituents K.

The alkylene group and the alkenylene group may be linear, branched, or cyclic, and the number of carbon atoms thereof is preferably 1 to 10, more preferably 1 to 5, still more preferably 1 or 2.

The number of carbon atoms of the arylene group is preferably 6 to 10, more preferably 6.

The number of carbon atoms of the heteroarylene group is preferably 4 to 10, more preferably 4 or 5.

The arylene group and the heteroarylene group may be monocyclic or polycyclic.

Examples of the group formed by linkage of two or more divalent linking groups include —COO—, —OCO—, —O-alkylene group-, —COO-alkylene group-, and —OCO-alkylene group-.

In particular, L is preferably a single bond, an arylene group, —COO—, or —COO-arylene group-.

V represents a single bond or a ((t2)+1)-valent linking group. t2 represents an integer of 1 or more. The upper limit is not particularly limited, but is preferably 5 or less, more preferably 2 or less, still more preferably 1.

The ((t2)+1)-valent linking group may be a group formed by removing ((t2)-1) hydrogen atoms from the divalent linking group represented by L.

V is preferably a single bond.

Each D independently represents the specific functional group. The definition and preferred form of the specific functional group are as described above.

When a plurality of groups represented by D are present, the plurality of groups represented by D may be the same or different.

The repeating unit B1 may be used alone or in combination of two or more.

When the compound B has the repeating unit B1, the content of the repeating unit B1 is preferably 50 to 100 mol %, more preferably 70 to 100 mol %, relative to all the repeating units of the compound B.

### Other Repeating Units

The compound B may have other repeating units other than the repeating unit B1.

Examples of the other repeating units include a repeating unit having an alkyl group optionally having a substituent, a repeating unit having a lactone group, a sultone group, or a carbonate group, and a repeating unit derived from an aromatic vinyl compound.

The definition and preferred form of the repeating unit having an alkyl group optionally having a substituent are as described in detail for the repeating unit A2.

The repeating unit having a lactone group, a sultone group, or a carbonate group is as described in detail for the repeating unit A3.

The repeating unit derived from an aromatic vinyl compound is as described in detail for the repeating unit A4.

In the compound B, the repeating unit having an alkyl group optionally having a substituent and the repeating unit having a lactone group, a sultone group, or a carbonate group may be used alone or in combination of two or more.

When the compound B has repeating units, the content of the repeating unit having an alkyl group optionally having a substituent is preferably 1 to 50 mol %, more preferably 10 to 30 mol %, relative to all the repeating units.

When the compound B has repeating units, the content of the repeating unit having a lactone group, a sultone group, or a carbonate group is preferably 1 to 50 mol %, more preferably 5 to 25 mol %, relative to all the repeating units.

When the compound B has repeating units, the content of the repeating unit derived from an aromatic vinyl compound is preferably 1 to 50 mol %, more preferably 10 to 45 mol %, relative to all the repeating units.

The compound B may be used alone or in combination of two or more.

The content of the compound B is preferably 5 to 80 mass %, more preferably 15 to 70 mass %, still more preferably 15 to 60 mass %, relative to the total solid contents of the resist composition.

### Solvent

The resist composition according to the present invention preferably includes a solvent.

The solvent preferably includes at least one of (M1) a propylene glycol monoalkyl ether carboxylate (e.g., propylene glycol monomethyl ether acetate (PGMEA)) or (M2) at least one selected from the group consisting of a propylene glycol monoalkyl ether (e.g., propylene glycol monomethyl ether (PGME) or propylene glycol monoethyl ether (PGEE)), a lactate (e.g., ethyl lactate), an acetate, an alkoxypropionate, a chain ketone (e.g., diacetone alcohol), a cyclic ketone (e.g., 2-heptanone, cyclohexanone, or cyclopentanone), a lactone (e.g., γ-butyrolactone), and an alkylene carbonate (e.g., propylene carbonate).

The solvent may further include a solvent other than the components (M1) and (M2).

The solvent preferably includes the component (M1). More preferably, the solvent consists substantially of the component (M1) or is a mixed solvent of the component (M1) and other components. In the latter case, the solvent still more preferably includes both the component (M1) and the component (M2).

The mass ratio (M1/M2) of the component (M1) to the component (M2) is preferably “100/0” to “0/100”, more preferably “100/0” to “15/85”, still more preferably “100/0” to “40/60”, particularly preferably “100/0” to “60/40”.

As described above, the solvent may further include components other than the components (M1) and (M2). In this case, the content of the components other than the components (M1) and (M2) is preferably 5 to 30 mass % relative to the total amount of the solvent.

The content of the solvent in the resist composition is preferably determined such that the concentration of solid contents is 0.5 to 30 mass %, more preferably 1 to 20 mass %.

### Other Additives

The resist composition according to the present invention may include other additives other than the above.

Examples of the other additives include surfactants, polymerization inhibitors, dissolution-inhibiting compounds, dyes, plasticizers, photosensitizers, light absorbents, and compounds that promote solubility in developers.

### Surfactant

The resist composition according to the present invention may further include a surfactant.

The surfactant is preferably a fluorine-based or silicon-based surfactant.

Examples of the fluorine-based surfactant and the silicon-based surfactant include surfactants disclosed in paragraphs [0218] and [0219] of WO2018/193954A.

The surfactant may be used alone or in combination of two or more.

When the resist composition includes a surfactant, the content of the surfactant is preferably 0.001 to 2 mass %, more preferably 0.01 to 1 mass %, relative to the total solid contents of the resist composition.

### Polymerization Inhibitor

The resist composition according to the present invention may further include a polymerization inhibitor.

The polymerization inhibitor is not particularly limited, but is preferably a radical polymerization inhibitor.

Examples of the polymerization inhibitor include a phenolic compound, a quinone compound, a free radical compound, an amine compound, a phosphine compound, and a thiol ether compound.

Examples of the phenolic compound include 4-methoxyphenol, hydroquinone, 2-tert-butylhydroquinone, 4-tert-butylcatechol, pentaerythritol tetrakis[3-(3,5-di-tert-butyl-4-hydroxyphenyl)propionate], 2,5-di-tert-butyl-4-methylphenol, 2,6-di-tert-butyl-p-cresol, 4,4′-thiobis(3-methyl-6-t-butylphenol), 2,2′-methylenebis(4-methyl-6-t-butylphenol), 4-methoxynaphthol, 2,4-bis(octylthiomethyl)-6-methylphenol, p-nitrosophenol, and α-nitroso-β-naphthol.

Examples of the quinone compound include 1,4-benzoquinone, 1,2-benzoquinone, and 1,4-naphthoquinone.

Examples of the free radical compound include 2,2,6,6-tetramethylpiperidine 1-oxyl (TEMPO), poly(4-methacryloyloxy-2,2,6,6-tetramethylpiperidine-N-oxyl), 4-hydroxy-2,2,6,6-tetramethylpiperidine 1-oxyl, 4-benzoyloxy-2,2,6,6-tetramethylpiperidine 1-oxyl, 2,2-diphenyl-1-picrylhydrazyl, and triphenylverdazyl.

The polymerization inhibitor may be used alone or in combination of two or more.

When the resist composition includes a polymerization inhibitor, the content of the polymerization inhibitor is preferably 0.001 to 15 mass %, more preferably 0.01 to 10 mass %, relative to the total solid contents of the resist composition.

### Resist Film and Pattern Forming Method

The procedure of a pattern forming method using the resist composition according to the present invention is not particularly limited, but the method preferably has the following steps. Each step may be performed once or a plurality of times.
Step 1: a step of forming a resist film on a substrate using the resist composition
Step 2: a step of exposing the resist film
Step 3: a step of developing the exposed resist film using a developer including an organic solvent to obtain a pattern

Hereinafter, the procedure of each step will be described in detail.

### Step 1: Resist Film Formation Step

The step 1 is a step of forming a resist film on a substrate using the resist composition.

The resist composition is as defined above.

One example of a method of forming a resist film on a substrate using the resist composition is application of the resist composition onto the substrate.

Before the application, the resist composition is preferably filtered through a filter as required. The pore size of the filter is preferably 0.1 m or less, more preferably 0.05 m or less, still more preferably 0.03 m or less. The filter is preferably made of polytetrafluoroethylene, polyethylene, or nylon.

The resist composition can be applied onto a substrate (e.g., silicon or silicon dioxide-coated) as used in manufacturing an integrated circuit element by an appropriate application method using a spinner, a coater, or the like. The application method is preferably spin coating using a spinner. The rotational speed in spin coating using a spinner is preferably 1,000 to 3,000 rpm.

After the application of the resist composition, the substrate may be dried to form a resist film. If necessary, various undercoat films (an inorganic film, an organic film, and an antireflection film) may be formed under the resist film.

For the material forming the substrate to be processed and the uppermost layer thereof, for example, in the case of a semiconductor wafer, a silicon wafer can be used, and examples of the material of the uppermost layer include Si, SiO₂, SiN, SiON, TiN, WSi, BPSG (boro-phospho. silicate glass), SOG (spin on glass), and organic antireflection films.

One example of a drying method is drying by heating. The heating can be performed using means provided in an ordinary exposure device and/or an ordinary development device, and may be performed using a hot plate or the like. The heating temperature is preferably 80° C. to 150° C., more preferably 80° C. to 140° C., still more preferably 80° C. to 130° C. The heating time is preferably 30 to 1,000 seconds, more preferably 60 to 800 seconds, still more preferably 60 to 600 seconds. The resist film can be formed by performing pre-baking, for example, at 60° C. to 150° C. for 1 to 20 minutes, preferably at 80° C. to 120° C. for 1 to 10 minutes.

The film thickness of the resist film is not particularly limited, but to enable formation of a more accurate fine pattern, it is preferably 10 to 120 nm. In particular, in the case of EUV exposure, the film thickness of the resist film is more preferably 10 to 65 nm, still more preferably 15 to 50 nm.

A topcoat may be formed on the resist film using a topcoat composition.

Preferably, the topcoat composition does not mix with the resist film and can further be uniformly applied on the resist film.

The thickness of the topcoat is preferably 10 to 200 nm, more preferably 20 to 100 nm, still more preferably 40 to 80 nm.

The topcoat is not particularly limited, and a topcoat known in the art can be formed by a method known in the art. For example, the topcoat can be formed on the basis of the descriptions in paragraphs [0072] to [0082] of JP2014-059543A.

For example, it is preferable to form a topcoat including a basic compound as described in JP2013-061648A on the resist film. Specific examples of the basic compound that can be included in the topcoat include basic compounds that may be included in the resist composition.

The topcoat also preferably includes a compound including at least one group or bond selected from the group consisting of an ether bond, a thioether bond, a hydroxy group, a thiol group, a carbonyl group, and an ester group.

### Step 2: Exposure Step

The step 2 is a step of exposing the resist film.

One example of a method of the exposure is irradiation of the formed resist film with an actinic ray or a radiation through a predetermined mask.

Examples of the actinic ray or the radiation include infrared light, visible light, ultraviolet light, far-ultraviolet light, extreme ultraviolet light, X-rays, and electron beams. Specific examples include KrF excimer laser (248 nm), ArF excimer laser (193 nm), F₂ excimer laser (157 nm), EUV (13 nm), X-rays, and electron beams.

After the exposure, post-exposure heat treatment (also referred to as post-exposure bake) is preferably performed before development. The post-exposure heat treatment promotes the reaction in exposed portions to provide higher sensitivity and a better pattern profile.

The heating temperature is preferably 80° C. to 150° C., more preferably 80° C. to 140° C., still more preferably 80° C. to 130° C.

The heating time is preferably 10 to 1,000 seconds, more preferably 10 to 180 seconds, still more preferably 30 to 120 seconds.

The heating can be performed using means provided in an ordinary exposure device and/or an ordinary development device, and may be performed using a hot plate or the like.

### Step 3: Development Step

The step 3 is a step of developing the exposed resist film using a developer including an organic solvent to form a pattern.

Examples of development methods include immersing the substrate in a tank filled with a developer for a certain period of time (dipping method), forming a puddle of a developer on the surface of the substrate by the action of surface tension and leaving it to stand for a certain period of time to achieve development (puddling method), spraying a developer onto the surface of the substrate (spraying method), and continuously ejecting a developer, while scanning a developer jetting nozzle at a constant rate, onto the substrate rotating at a constant rate (dynamic dispensing method).

After the step of performing development, a step of stopping the development while performing replacement with another solvent may be performed.

The developing time is not particularly limited as long as the resin in unexposed portions is sufficiently dissolved, and is preferably 10 to 300 seconds, more preferably 20 to 120 seconds.

The temperature of the developer is preferably 0° C. to 50° C., more preferably 15° C. to 35° C.

The organic solvent included in the developer is preferably at least one selected from the group consisting of a ketone solvent, an ester solvent, an alcohol solvent, an amide solvent, an ether solvent, and a hydrocarbon solvent.

The ClogP value of the organic solvent included in the developer is not particularly limited, but is preferably 0.00 or more, more preferably 1.00 or more. When two or more organic solvents are included, the ClogP value of a mixed solvent thereof is preferably in the above range.

Examples of the ketone solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate.

Examples of the ester solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxy propionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, and butyl propionate.

As the alcohol solvent, the amide solvent, the ether solvent, and the hydrocarbon solvent, for example, solvents disclosed in paragraphs [0715] to [0718] of US2016/0070167A can be used.

The above solvents may be mixed with each other or may be mixed with a solvent other than the above or water. The developer as a whole has a moisture content of preferably less than 50 mass %, more preferably less than 20 mass %, still more preferably less than 10 mass %, and particularly preferably includes substantially no moisture.

The content of the organic solvent in the developer is preferably 50 to 100 mass %, more preferably 80 to 100 mass %, still more preferably 90 to 100 mass %, particularly preferably 95 to 100 mass %, relative to the total amount of the developer.

For the advantageous effect of the present invention to be better produced, the developer preferably includes a first organic solvent and a second organic solvent, and more preferably, the boiling point of the first organic solvent is higher than the boiling point of the second organic solvent and the ClogP value of the first organic solvent is larger than the ClogP value of the second organic solvent. The boiling point means a boiling point at 1 atm (760 mmHg).

The content ratio of the first organic solvent to the second organic solvent in the developer is not particularly limited, but for the advantageous effect of the present invention to be better produced, the mass ratio of the content of the second organic solvent to the content of the first organic solvent is preferably 1 to 50, more preferably 3 to 20.

For the advantageous effect of the present invention to be better produced, the second organic solvent in the developer is preferably the ketone solvent or the ester solvent, more preferably the ester solvent, still more preferably butyl acetate or isoamyl butyrate. The first organic solvent is not particularly limited, but is preferably an organic solvent having a ClogP value of 3.00 or more, more preferably a hydrocarbon solvent.

### Step 4: Rinsing Step

The pattern forming method preferably includes, after the step 3, a step 4 of washing the pattern using a rinsing liquid including an organic solvent.

The rinsing liquid includes an organic solvent.

The organic solvent included in the rinsing liquid is preferably at least one organic solvent selected from the group consisting of a hydrocarbon solvent, a ketone solvent, an ester solvent, an alcohol solvent, an amide solvent, and an ether solvent.

Examples of the hydrocarbon solvent, the ketone solvent, the ester solvent, the alcohol solvent, the amide solvent, and the ether solvent include those which are the same as those described for the developer including an organic solvent.

Examples of methods of the rinsing step include, but are not limited to, continuously ejecting the rinsing liquid onto the substrate rotating at a constant rate (spin-coating method), immersing the substrate in a tank filled with the rinsing liquid for a certain period of time (dipping method), and spraying the rinsing liquid onto the surface of the substrate (spraying method).

The pattern forming method according to the present invention may include a heating step (post bake) after the rinsing step. In this step, the developer and the rinsing liquid remaining between and within patterns are removed by baking. In addition, this step also has an effect of annealing the resist pattern to improve the surface roughness of the pattern. The heating step after the rinsing step is preferably performed at 40° C. to 250° C. (preferably 90° C. to 200° C.) for 10 seconds to 3 minutes (preferably 30 seconds to 120 seconds).

The pattern formed may be used as a mask to perform etching treatment on the substrate, which is an object to be etched. Specifically, the pattern formed in the step 3 may be used as an etching mask to process the substrate (or an underlayer film and the substrate), thereby forming a pattern on the substrate.

The method of processing the substrate (or an underlayer film and the substrate) is not particularly limited, but a preferred method is to perform dry etching on the substrate (or an underlayer film and the substrate) using the pattern formed in the step 3 as a mask, thereby forming a pattern on the substrate. The dry etching is preferably oxygen plasma etching.

For the advantageous effect of the present invention to be better produced, when the pattern forming method does not have the step 4, the developer preferably includes two or more organic solvents, and when the pattern forming method has the step 4, at least one of the developer or the rinsing liquid preferably includes two or more organic solvents.

The two or more organic solvents included in the developer and the rinsing liquid are preferably a combination of the first organic solvent and the second organic solvent described above.

The resist composition and various materials used in the pattern forming method according to the present invention (e.g., solvents, developers, rinsing liquids, compositions for antireflection film formation, and compositions for topcoat formation) are preferably free of impurities such as metals. The content of impurities included in these materials is preferably 1 mass ppm or less, more preferably 10 mass ppb or less, still more preferably 100 mass ppt or less, particularly preferably 10 mass ppt or less, most preferably 1 mass ppt or less. Examples of metal impurities include Na, K, Ca, Fe, Cu, Mg, Al, Li, Cr, Ni, Sn, Ag, As, Au, Ba, Cd, Co, Pb, Ti, V, W, and Zn.

One example of a method of removing impurities such as metals from the various materials is filtration using a filter. Details of the filtration using a filter are described in paragraph [0321] of WO2020/004306A.

Examples of methods of reducing the amount of impurities such as metals included in the various materials include selecting raw materials with low metal contents as raw materials constituting the various materials, performing filter filtration on raw materials constituting the various materials, and performing distillation under conditions where contamination is minimized by, for example, lining the inside of an apparatus with Teflon (registered trademark).

Instead of filter filtration, an adsorbent may be used to remove impurities, or filter filtration and an adsorbent may be used in combination. The adsorbent may be a known adsorbent, and, for example, inorganic-based adsorbents such as silica gel and zeolite and organic-based adsorbents such as activated carbon can be used. To reduce the amount of impurities such as metals included in the various materials, entry of metal impurities during the production process needs to be prevented. Whether metal impurities are sufficiently removed from a production apparatus can be determined by measuring the content of metal components included in a washing solution used to wash the production apparatus. The content of metal components included in the used washing solution is preferably 100 mass ppt (parts per trillion) or less, more preferably 10 mass ppt or less, still more preferably 1 mass ppt or less.

### Method for Producing Electronic Device

The present invention also relates to a method for producing an electronic device, the method including the above-described pattern forming method, and an electronic device produced by the production method.

The electronic device according to the present invention is suitably mounted on electric or electronic equipment (e.g., household appliances, office automation (OA), media-related equipment, optical equipment, and communication equipment).

### Examples

The present invention will now be described in more detail with reference to Examples.

The materials, amounts, proportions, treatments, treatment sequences, etc. given in the following Examples may be changed as appropriate without departing from the spirit of the present invention. Thus, the scope of the present invention should not be construed as being limited by the Examples given below.

### Components of Resist Composition

The components used to prepare resist compositions used in Examples and Comparative Examples and the materials used in the evaluations described later will be described below.

### Compound A

The structures of compounds A (A-1 to A-18) used to prepare the resist compositions are shown below. For polymers having a repeating unit, the weight-average molecular weight (Mw) is shown on the right of each compound. The number attached to each repeating unit represents the content (mol %) of the repeating unit relative to all the repeating units in the polymer.

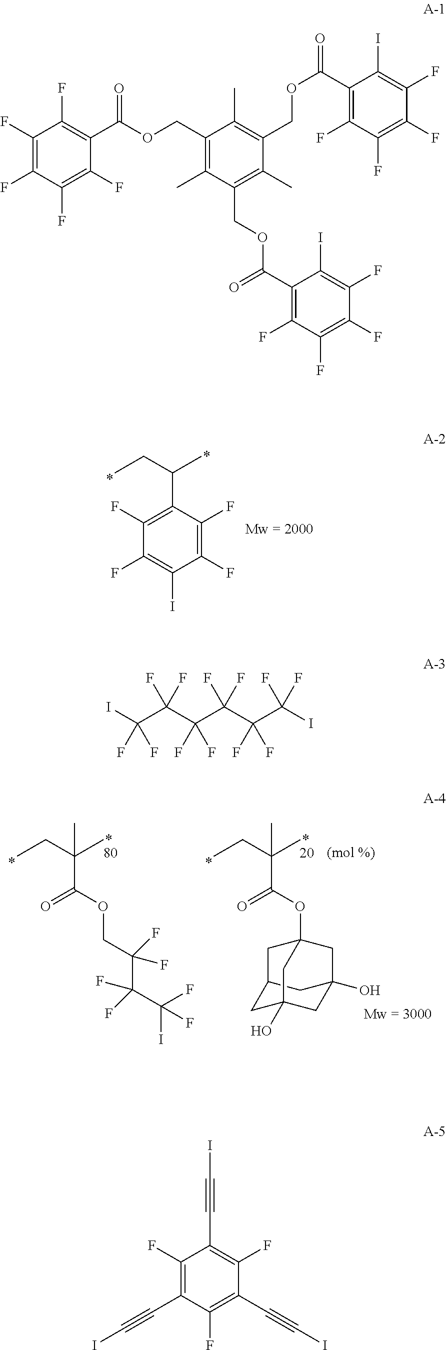

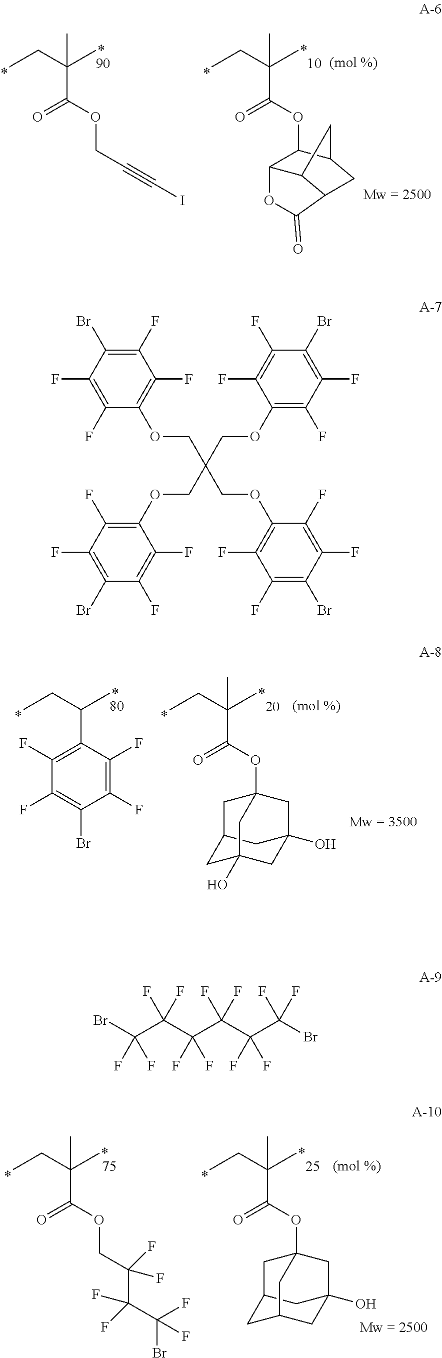

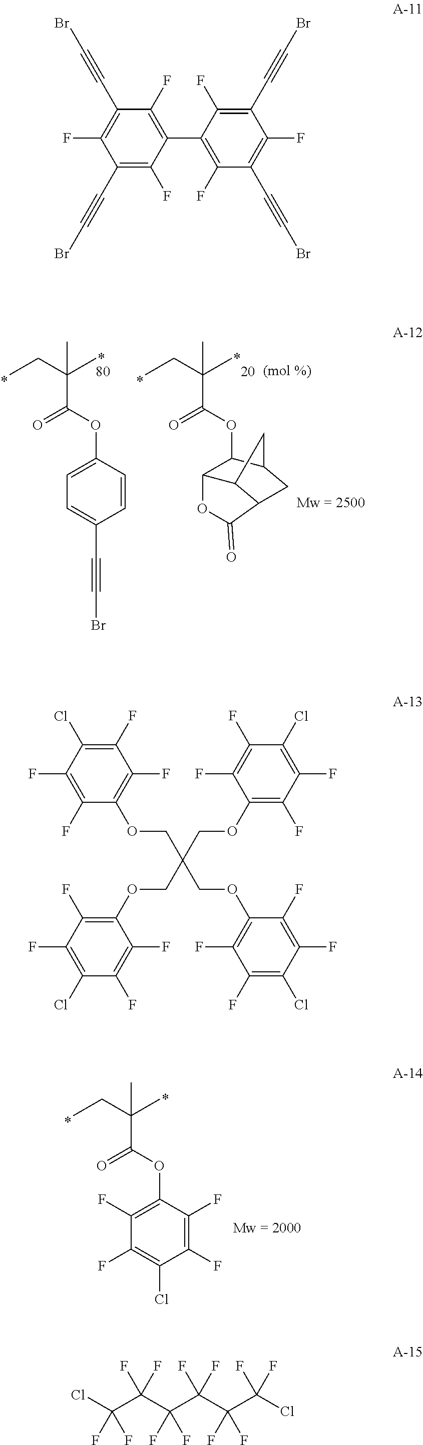

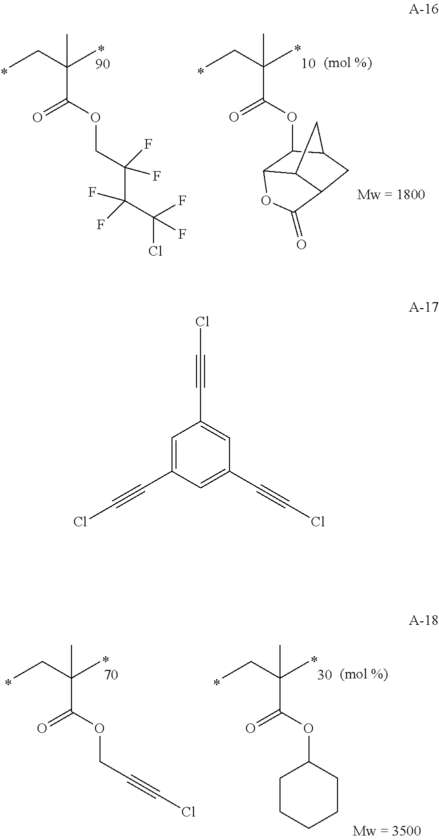

### Compound B

The structures of compounds B (B-1 to B-16) used to prepare the resist compositions are shown below. For polymers having a repeating unit, the weight-average molecular weight (Mw) is shown on the right of each compound. The number attached to each repeating unit represents the content (mol %) of the repeating unit relative to all the repeating units in the polymer.

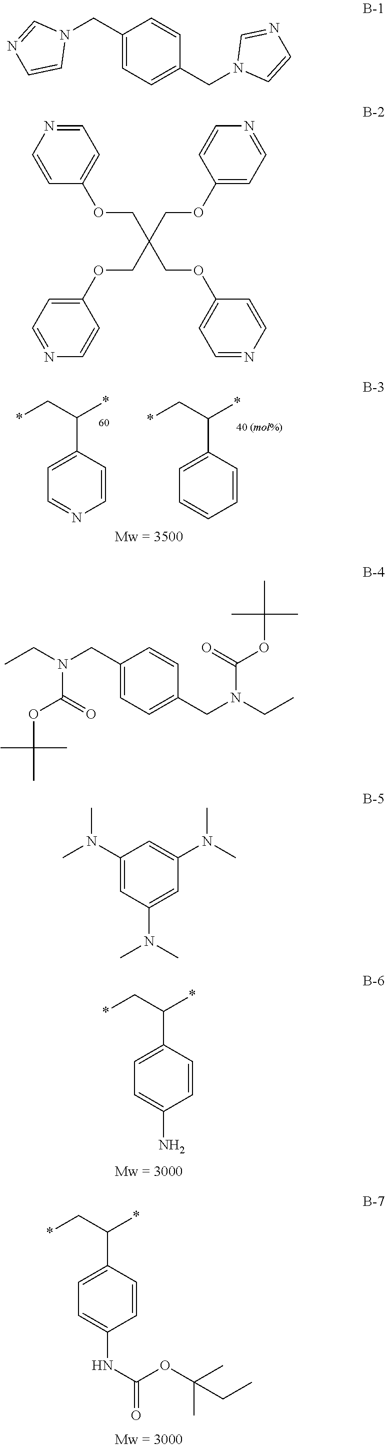

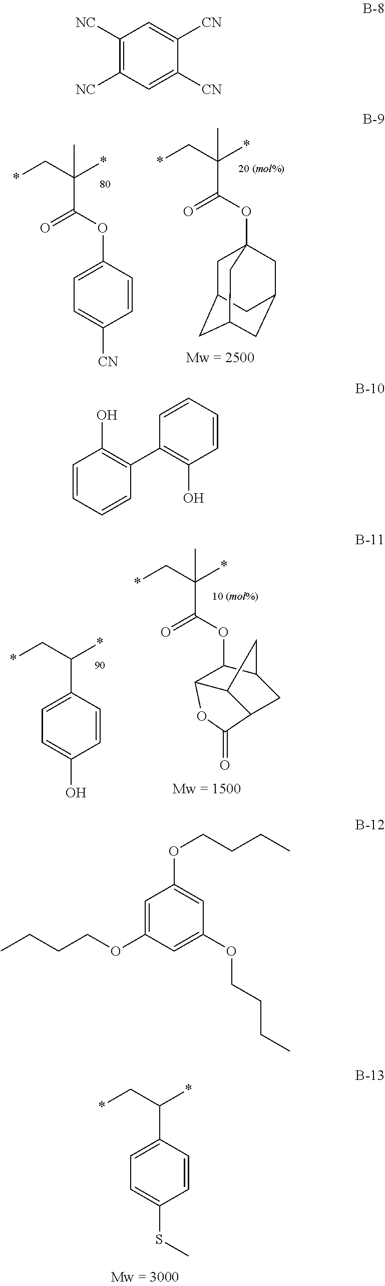

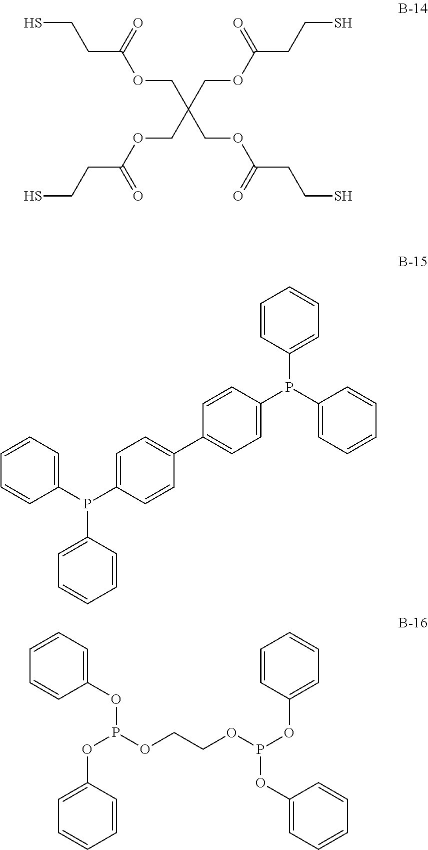

### Additive C

Additives C (C-1 to C-5) used to prepare the resist compositions are shown below.
C-1: MEGAFACE F176 (manufactured by DIC Corporation, fluorine-based surfactant)
C-2: MEGAFACE R08 (manufactured by DIC Corporation, fluorine and silicon-based surfactant)
C-3: PF656 (manufactured by OMNOVA Solutions Inc., fluorine-based surfactant)
C-4: 2,6-di-tert-butyl-p-cresol (polymerization inhibitor)
C-5: a compound having the following structure (polymerization inhibitor)

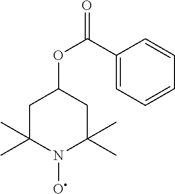

### Solvent (F)

Solvents F (F-1 to F-9) used to prepare the resist compositions are shown below.
F-1: propylene glycol monomethyl ether acetate (PGMEA)
F-2: propylene glycol monomethyl ether (PGME)
F-3: propylene glycol monoethyl ether (PGEE)
F-4: cyclohexanone
F-5: cyclopentanone
F-6: 2-heptanone
F-7: ethyl lactate
F-8: γ-butyrolactone
F-9: propylene carbonate

### Solvent d

Solvents d (d-1 to d-9) used as developers in the evaluations are shown below.
d-1: 2-heptanone
d-2: isobutyl propionate
d-3: diisobutyl ether
d-4: n-undecane
d-5: 4-methyl-2-pentanol
d-6: PGMEA
d-7: butyl acetate
d-8: N-methyl-2-pyrrolidone
d-9: diisobutyl ketone

### Comparative Compounds

The structures of comparative compounds (Z-1 to Z-4) used to prepare the resist compositions of Comparative Examples are shown below. In the structural formulas, numerical values shown as Mw represent weight-average molecular weights.

Comparative compounds Z-1 and Z-2 were used as resins, comparative compound Z-3 was used as a photoacid generator, and comparative compound Z-4 was used as a photodegradable base.

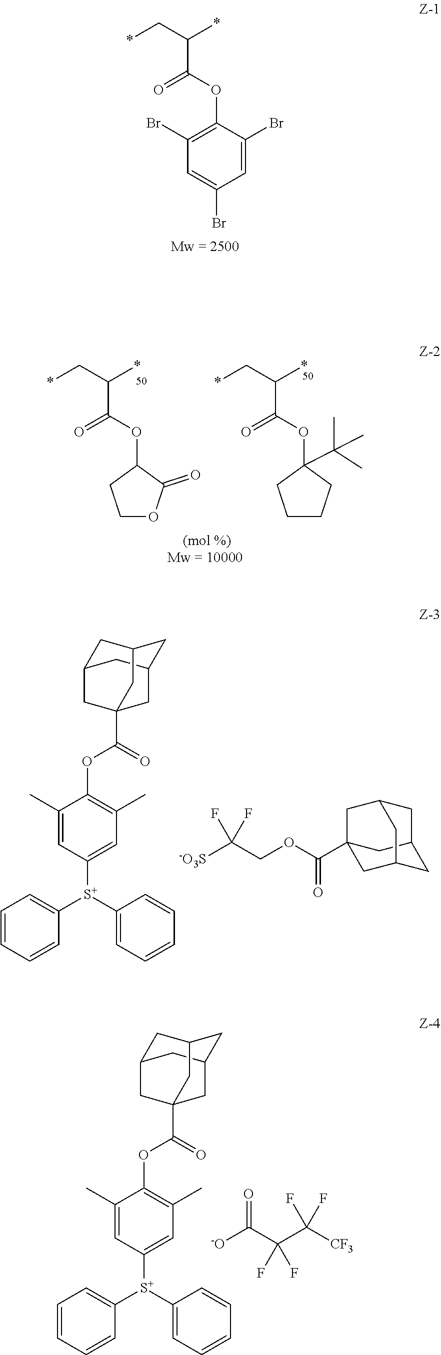

### Preparation of Resist Composition

Components shown in Table 1 and Table 2 below were mixed together so as to achieve a concentration of solid contents (total solid contents) of 1.6 mass %. The resulting mixed solutions were each filtered through a polyethylene filter having a pore size of 0.03 m to prepare resist compositions.

The term “solid contents (total solid contents)” refers to all components other than solvents.

In Table 1 and Table 2, the “Mass %” column shows the content (mass %) of each solid component relative to the total solid contents. Solid contents mean components excluding solvents.

In Table 1 and Table 2, entries separated by “/” in the “Type” column each indicate that a plurality of compounds are included, and entries separated by “/” in the “Mixing ratio” column each indicate the mixing ratio (mass ratio) of the plurality of compounds. For example, “Solvent F” of the resist composition “Re-10” includes “F-1”, “F-2”, and “F-8”, and their contents are “70”, “25”, and “5” mass %, respectively.

TABLE 1

| | Resist composition | | | | | | | |
|---|---|---|---|---|---|---|---|---|
| | | | | | | | Solvent F | |
| | Compound A | | Compound B | | Additive C | | | Mixing |
| Table 1 | Type | Mass % | Type | Mass % | Type | Mass % | Type | ratio |
| Re-1 | A-1 | 40.0 | B-3 | 60.0 | — | — | F-1 | 100 |
| Re-2 | A-2 | 65.0 | B-8 | 35.0 | — | — | F-1/F-3 | 70/30 |
| Re-3 | A-3 | 40.0 | B-9 | 60.0 | — | — | F-1/F-6 | 40/60 |
| Re-4 | A-4 | 70.0 | B-10 | 29.9 | C-1 | 0.1 | F-1/F-5 | 50/50 |
| Re-5 | A-5 | 65.0 | B-11 | 35.0 | — | — | F-1/F-2 | 60/40 |
| Re-6 | A-6 | 75.0 | B-12 | 25.0 | — | — | F-1/F-2 | 70/30 |
| Re-7 | A-7 | 44.9 | B-3 | 55.0 | C-2 | 0.1 | F-1 | 100 |
| Re-8 | A-8 | 70.0 | B-1 | 30.0 | — | — | F-1/F-9 | 90/10 |
| Re-9 | A-9 | 35.0 | B-13 | 65.0 | — | — | F-1 | 100 |
| Re-10 | A-10 | 70.0 | B-14 | 30.0 | — | — | F-1/F-2/F-8 | 70/25/5 |
| Re-11 | A-11 | 40.0 | B-7 | 60.0 | — | — | F-7 | 100 |
| Re-12 | A-12 | 55.0 | B-15 | 45.0 | — | — | F-1/F-8 | 85/15 |
| Re-13 | A-13 | 45.0 | B-3 | 55.0 | — | — | F-1/F-7 | 80/20 |
| Re-14 | A-14 | 64.9 | B-5 | 35.0 | C-3 | 0.1 | F-1/F-8 | 85/15 |
| Re-15 | A-15 | 30.0 | B-6 | 70.0 | — | — | F-4 | 100 |
| Re-16 | A-16 | 55.0 | B-2 | 45.0 | — | — | F-1/F-5 | 50/50 |
| Re-17 | A-17 | 35.0 | B-11 | 65.0 | — | — | F-1/F-2 | 70/30 |
| Re-18 | A-18 | 70.0 | B-4 | 30.0 | — | — | F-1/F-5 | 50/50 |
| Re-19 | A-6 | 50.0 | B-7 | 50.0 | — | — | F-1 | 100 |
| Re-20 | A-8 | 47.5 | B-6 | 47.5 | C-4 | 5.0 | F-1 | 100 |
| Re-21 | A-14 | 50.0 | B-3 | 50.0 | — | — | F-1 | 100 |
| Re-22 | A-2 | 60.0 | B-16 | 40.0 | — | — | F-1/F-3 | 70/30 |
| Re-23 | A-7/A-9 | 30.0/35.0 | B-6 | 35.0 | — | — | F-1 | 100 |
| Re-24 | A-7 | 42.0 | B-3 | 50.0 | C-5 | 8.0 | F-1 | 100 |
| Re-25 | A-13 | 44.0 | B-3/B-6 | 33.0/33.0 | — | — | F-1/F-7 | 80/20 |
| Re-26 | A-2/A-3 | 50.0/10.0 | B-2 | 40.0 | — | — | F-1/F-3 | 70/30 |
| Re-27 | A-17 | 30.0 | B-2/B-6 | 10.0/60.0 | — | — | — | — |
| Re-C1 | A-1 | 40.0 | B-1 | 60.0 | — | — | F-1 | 100 |
| Re-C2 | Z-1 | 70.0 | B-1 | 30.0 | — | — | F-1/F-9 | 90/10 |

TABLE 2

| | Resist composition | | | | | | | |
|---|---|---|---|---|---|---|---|---|
| | | | Photoacid | | Photode- | | Solvent F | |
| | Resin | | generator | | gradable base | | | Mixing |
| Table 2 | Type | Mass % | Type | Mass % | Type | Mass % | Type | ratio |
| Re-C3 | Z-2 | 88.0 | Z-3 | 7.0 | Z-4 | 5.0 | F-1/F-2 | 60/40 |

### Pattern Formation and Evaluation

According to the procedure described below, the pattern resolution was evaluated using patterns obtained by EUV exposure using the resist compositions of Examples and Comparative Examples.

### Pattern Formation

A composition AL412 for underlayer film formation (manufactured by Brewer Science, Inc.) was applied onto a silicon wafer with a diameter of 12 inches and baked at 205° C. for 60 seconds to form an undercoat film having a film thickness of 20 nm. A resist composition shown in Table 2 was applied thereonto and baked at 100° C. for 60 seconds to form a resist film having a film thickness of 30 nm.

The obtained silicon wafer having the resist film was subjected to pattern irradiation using an EUV exposure apparatus (Micro Exposure Tool manufactured by Exitech Ltd., NA: 0.3, Quadrupole, outer sigma: 0.68, inner sigma: 0.36) so as to provide a pattern with an average line width of 20 nm. As a reticle, a mask having a line size of 20 nm and a line-to-space ratio of 1:1 was used.

The resist film after the exposure was baked at 90° C. for 60 seconds and then developed with a developer shown in Table 3 for 30 seconds, and this was spin-dried to obtain a positive pattern.

### Resolution Evaluation (Limiting Resolution, nm)

In Pattern Formation above, the exposure was performed at an optimal exposure dose Eop (μC/cm²) (an exposure dose at which the pattern formed using the resist composition was a reproduction of the pattern of the mask used for the exposure).

Next, a test in which line-and-space patterns were formed while the exposure dose was gradually changed from the optimal exposure dose Eop was performed. At this time, the minimum size of a pattern that was resolved without collapse was determined using a critical dimension scanning electron microscope (SEM (S-9380II, Hitachi Ltd.)), and this was used as the “resolution (nm)”. Smaller resolution values indicate better resolution.

The resolution is preferably 15.0 nm or less, more preferably 13.0 nm or less, most preferably 11.0 nm or less.

### Cross-Sectional Rectangularity Evaluation

The cross-sectional rectangularity was evaluated using the line-and-space patterns of Examples and Comparative Examples formed in Pattern Formation above.

The cross-sectional profiles of the line patterns of Examples and Comparative Examples having an average line width of 20 nm were observed under a critical dimension scanning electron microscope (SEM, S-9380II manufactured by Hitachi, Ltd.), and a pattern line width Lb at the bottom of each resist pattern and a pattern line width La at the top of each resist pattern were measured.

Using the values of La/Lb as indicators, the cross-sectional rectangularity of the pattern profiles was evaluated according to the following criteria. S is the best, and E is the worst. For practical purposes, the grade D or higher is desirable.

### Evaluation Criteria

$$\begin{matrix}S : 1. \leq ( La / Lb ) \leq 1.01 \\ A : 1.01 < ( La / Lb ) \leq 1.02 \\ B : 1.02 < ( La / Lb ) \leq 1.03 \\ C : 1.03 < ( La / Lb ) \leq 1.04 \\ D : 1.04 < ( La / Lb ) \leq 1.05 \\ E : 1.05 < ( La / Lb )\end{matrix}$$

### Results

The results of the evaluations are shown in Table 3. The composition of developers (D-1 to D-9) shown in Table 3 is shown in Table 4.

In Table 4, numerical values in the columns of “Mass %” each indicate the content (mass %) of each solvent d mentioned above relative to the total mass of the developer.

TABLE 3

| | Resist | | | Cross-sectional |
|---|---|---|---|---|
| Table 3 | composition | Developer | Resolution | rectangularity |
| Example 1 | Re-1 | D-1 | 10.7 | A |
| Example 2 | Re-2 | D-3 | 12.5 | A |
| Example 3 | Re-3 | D-5 | 11.9 | A |
| Example 4 | Re-4 | D-7 | 12.8 | A |
| Example 5 | Re-5 | D-2 | 12.2 | A |
| Example 6 | Re-6 | D-4 | 11.5 | A |
| Example 7 | Re-7 | D-1 | 10.2 | S |
| Example 8 | Re-8 | D-6 | 10.5 | S |
| Example 9 | Re-9 | D-8 | 12 | S |
| Example 10 | Re-10 | D-1 | 12.1 | S |
| Example 11 | Re-11 | D-9 | 10.9 | S |
| Example 12 | Re-12 | D-2 | 12.5 | S |
| Example 13 | Re-13 | D-1 | 10.4 | S |
| Example 14 | Re-14 | D-5 | 10.4 | S |
| Example 15 | Re-15 | D-7 | 10.6 | S |
| Example 16 | Re-16 | D-3 | 10.4 | S |
| Example 17 | Re-17 | D-2 | 12.5 | S |
| Example 18 | Re-18 | D-5 | 10.9 | S |
| Example 19 | Re-19 | D-6 | 10.5 | S |
| Example 20 | Re-20 | D-4 | 10.6 | S |
| Example 21 | Re-21 | D-9 | 10.3 | S |
| Example 22 | Re-22 | D-3 | 12.8 | A |
| Example 23 | Re-23 | D-1 | 10.9 | S |
| Example 24 | Re-24 | D-1 | 10.6 | S |
| Example 25 | Re-25 | D-1 | 10.5 | S |
| Example 26 | Re-26 | D-3 | 10.6 | A |
| Example 27 | Re-27 | D-2 | 10.4 | S |
| Comparative | Re-C1 | D-1 | 19.8 | E |
| Example 1 | | | | |
| Comparative | Re-C2 | D-4 | 19.6 | E |
| Example 2 | | | | |
| Comparative | Re-C3 | D-9 | 19.9 | E |
| Example 3 | | | | |

TABLE 4

| Developer | |
|---|---|
| First solvent | Second solvent |

| Table 4 | Type | Mass % | Type | Mass % |
|---|---|---|---|---|
| D-1 | d-1 | 100.0 | — | — |
| D-2 | d-1 | 80.0 | d-2 | 20.0 |
| D-3 | d-1 | 75.0 | d-3 | 25.0 |
| D-4 | d-1 | 85.0 | d-4 | 15.0 |
| D-5 | d-5 | 85.0 | d-4 | 15.0 |
| D-6 | d-6 | 70.0 | d-4 | 30.0 |
| D-7 | d-7 | 90.0 | d-4 | 10.0 |
| D-8 | d-1 | 95.0 | d-8 | 5.0 |
| D-9 | d-9 | 100.0 | — | — |

The results in Table 3 have confirmed that the resist composition (actinic ray-sensitive or radiation-sensitive resin composition) according to the present invention is excellent in resolution. It has also been confirmed that the resist composition according to the present invention is excellent also in cross-sectional rectangularity.

In contrast, the resist compositions Re—C1 to Re—C5 used in Comparative Examples 1 to 5 are insufficient in resolution and cross-sectional rectangularity.

Comparison of Examples 1 to 6 with other Examples has confirmed that regarding the compound A, when X in formulas (A1) to (A3) represents a bromine atom or a chlorine atom, the cross-sectional rectangularity of a pattern formed using the resist composition is superior.

Comparison of Examples 2 to 6, 9, 10, 12, and 17 with other Examples has confirmed that regarding the compound B, when the specific functional group is a functional group selected from the group consisting of a nitrogen-containing aromatic heterocyclic group, NH₂—, an NH₂ group protected with a removable protecting group, NHR^{N1}—, an NH^{N1} group protected with a removable protecting group, and NR^{N2}₂—, the resolution of a pattern formed using the resist composition is superior.

What is claimed is:

1. A composition comprising:
a compound A having a plurality of groups that are each a group represented by any one of formula (A1) to formula (A3); and
a compound B having a plurality of specific functional groups that are each a specific functional group selected from the group consisting of a nitrogen-containing aromatic heterocyclic group, —NH₂, an NH₂ group protected with a removable protecting group, —NHR^{N1}, an NHR^{N1} group protected with a removable protecting group, —NR^{N2}₂, —C≡N, —OH, —OR^{O}, —SH, —SR^{S}, —PR^{P1}₂, and —P(OR^{P2})₂
the composition satisfying at least one of requirement 1 or requirement 2:
Requirement 1: The compound A is a polymer having a repeating unit including the group represented by any one of formula (A1) to formula (A3),
Requirement 2: The compound B is a polymer having a repeating unit including the specific functional group,
wherein R^{N1}, R^{N2}, R^{O}, R^{S}, R^{P1}, and R^{P2} each independently represent a monovalent hydrocarbon group optionally having a substituent, monovalent hydrocarbon groups represented by R^{N2} may be bonded to each other to form a ring, monovalent hydrocarbon groups represented by R^{P1} may be bonded to each other to form a ring, and monovalent hydrocarbon groups represented by R^{P2} may be bonded to each other to form a ring, 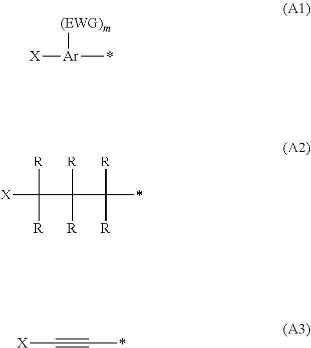
in formula (1,
X represents an iodine atom, a bromine atom, or a chlorine atom,
EWG represents an electron-withdrawing group,
m represents an integer of 4 or more, and
Ar represents an aromatic hydrocarbon ring optionally having a substituent,
in formula (A2),
X represents an iodine atom, a bromine atom, or a chlorine atom, and
each R independently represents a hydrogen atom or a substituent, provided that at least one R represents an electron-withdrawing group,
in formula (A3),
X represents an iodine atom, a bromine atom, or a chlorine atom, and
* represents a bonding position.

2. The composition according to claim 1, wherein in formula (A1) to formula (A3), X represents a bromine atom or a chlorine atom.

3. The composition according to claim 1, wherein in formula (A2), every R represents an electron-withdrawing group.

4. The composition according to claim 1, wherein in formula (A1), EWG represents a fluorine atom or a cyano group, and in formula (A2), at least one R represents a fluorine atom or a cyano group.

5. The composition according to claim 1, wherein the compound Ais a compound having a plurality of groups represented by formula (A1).

6. The composition according to claim 1, wherein the specific functional group is a functional group selected from the group consisting of a nitrogen-containing aromatic heterocyclic group, NH₂—, an NH₂ group protected with a removable protecting group, NHR^{N1}—, an NHR^{N1} group protected with a removable protecting group, and NR^{N2}₂—.

7. The composition according to claim 1, satisfying requirement 1.

8. The composition according to claim 1, satisfying requirement 2.

9. A resist film formed using the composition according to claim 1.

10. A pattern forming method comprising:
a step of forming a resist film on a substrate using the composition according to claim 1;
a step of exposing the resist film; and
a step of developing the exposed resist film using a developer including an organic solvent.

11. A method for producing an electronic device, the method comprising the pattern forming method according to claim 10.

12. The composition according to claim 2, wherein in formula (A2), every R represents an electron-withdrawing group.

13. The composition according to claim 2, wherein in formula (A1), EWG represents a fluorine atom or a cyano group, and in formula (A2), at least one R represents a fluorine atom or a cyano group.

14. The composition according to claim 2, wherein the compound A is a compound having a plurality of groups represented by formula (A1).

15. The composition according to claim 2, wherein the specific functional group is a functional group selected from the group consisting of a nitrogen-containing aromatic heterocyclic group, NH₂—, an NH₂ group protected with a removable protecting group, NHR^{N1}—, an NHR^{N1} group protected with a removable protecting group, and NR^{N2}₂—.

16. The composition according to claim 2, satisfying requirement 1.

17. The composition according to claim 2, satisfying requirement 2.

18. A resist film formed using the composition according to claim 2.

19. A pattern forming method comprising:
a step of forming a resist film on a substrate using the composition according to claim 2;
a step of exposing the resist film; and
a step of developing the exposed resist film using a developer including an organic solvent.
